(19) United States
(12) Patent Application Publication
(10) Pub. No.: US 2016/0099076 A1
(43) Pub. Date: Apr. 7, 2016

(54) SEMICONDUCTOR MEMORY DEVICE

(71) Applicant: SK hynix Inc., Gyeonggi-do (KR)

(72) Inventor: Sang-Mook OH, Gyeonggi-do (KR)

(21) Appl. No.: 14/667,144

(22) Filed: Mar. 24, 2015

(30) Foreign Application Priority Data
Oct. 1, 2014 (KR) 10-2014-0132576

(51) Int. Cl. G11C 29/40; G11C 29/36

(52) U.S. Cl. CPC G11C 29/40; G11C 29/36; G11C 2029/4002

(57) ABSTRACT

A semiconductor memory device includes a memory bank divided into a plurality of test areas which provide test data for a data compression test operation, a data compressing unit suitable for generating compressed data based on the test data, a data converting unit suitable for converting the compressed data into analog data to generate a final compressed data, and an output unit suitable for outputting the final compressed data during a read operation for the data compression test operation.

### CROSS-REFERENCE TO RELATED APPLICATIONS

The present application claims priority of Korean Patent Application No. 10-2014-0132576, filed on Oct. 1, 2014, which is incorporated herein by reference in its entirety.

### BACKGROUND

1. Field

Exemplary embodiments of the present invention relate to a semiconductor designing technology, and more particularly, to a semiconductor memory device capable of performing a data compression test operation.

2. Description of the Related Art

As progress has been made in the fabrication of semiconductor memory devices, such as Double Data Rate Synchronous Dynamic Random Access Memory (DDR SDRAM), the degree of integration has increased dramatically. The increase in integration degree of semiconductor memory devices signifies that the semiconductor memory devices have an increased number of memory cells. The number of memory cells in a semiconductor memory device is the basic factor for determining the capacity of data that may be stored in the semiconductor memory device. Therefore, the first thing to consider in satisfying user demand for large capacity semiconductor memory devices is increasing the number of memory cells in the semiconductor memory device.

The more memory cells a semiconductor memory device has, the better it processes data. However, for the tester who decides whether the semiconductor memory device is satisfactory or defective, it is a burden to test all the memory cells of each semiconductor memory device. That is, it is really difficult to test hundreds and thousands of memory cells of each semiconductor memory device, and it takes a long time to test the hundreds and thousands of memory cells and decide whether each of the memory cells is in satisfactory condition or is failed. Particularly, since the test time is included in the production cost for the manufacturer who produces the semiconductor memory devices, the production cost of the semiconductor memory devices is increased as the test time becomes longer. The increased production cost deteriorates market competitiveness of the semiconductor memory devices.

Therefore, many solutions for more efficient test operations are being suggested, and among them is a data compression test. Data compression tests are performed by storing predetermined test data in a plurality of memory cells, compressing the test data, and outputting the compressed test data. A test performer may decide whether the plurality of the memory cells are normal or defective based on the outputted compressed data. The basic purpose of the data compression test operation is to save time required for deciding whether the memory cells are normal or defective, and the number of channels used for the data compression test operation is minimized in this respect.

FIGS. 1 and 2 are block diagrams illustrating a data compression test operation of a semiconductor memory device according to prior art. FIG. 1 shows, as an example, a semiconductor memory device performing a data compression test operation by dividing a memory bank 110 into two test areas.

Referring to FIG. 1, the semiconductor memory device includes the memory bank 110, a first data compressing unit 120, a second data compressing unit 130, a first buffering unit 140, a second buffering unit 150, and an output multiplexing unit 160.

The memory bank 110 includes a plurality of memory cells for storing data. It is described as an example that the memory bank 110 is divided into 8 memory regions, which are first to eighth memory regions 111, 112, 113, 114, 115, 116, 117 and 118. A test data having a predetermined logic level value is stored in each of the first to eighth memory regions 111, 112, 113, 114, 115, 116, 117 and 118 during the data compression test operation.

The first data compressing unit 120 generates a first compressed data DAT_CMP1 by compressing the test data provided by the first to fourth memory regions 111, 112, 113 and 114. The second data compressing unit 130 generates a second compressed data DAT_CMP2 by compressing the test data provided by the fifth to eighth memory regions 115, 116, 117 and 118. Hereafter, the first to fourth memory regions 111, 112, 113 and 114 are referred to as ‘a first test area’, and the fifth to eighth memory regions 115, 116, 117 and 118 are referred to as ‘a second test area’.

The first data con pressing unit 120 receives the test data outputted from the first test area, detects whether the test data have the same logic level value, and outputs the detection result as the first compressed data DAT_CMP1. The second data compressing unit 130 receives the test data outputted from the second test area, detects whether the test data have the same logic level value, and outputs the detection result as the second compressed data DAT_CMP2. Herein, the logic level values of the first compressed data DAT_CMP1 and the second compressed data DAT_CMP2 are decided based on the detection results.

Subsequently, the first buffering unit 140 and the second buffering unit 150 buffer the first compressed data DAT_CMP1 and the second compressed data DAT_CMP2 and output the buffered data, respectively. The output multiplexing unit 160 outputs an output signal of the first buffering unit 140 or an output signal of the second buffering unit 150 to an output pad DOUT in response to an output control signal CTR_OUT. Herein, the output control signal CTR_OUT is enabled during a read operation for a data compression test operation. As the read operation for the data compression test operation is performed twice, the output multiplexing unit 160 may sequentially output the output signal of the first buffering unit 140 and the output signal of the second buffering unit 150.

As illustrated in the drawing, the first compressed data DAT_CMP1 is a compression result of compressing the first test area, which includes the first to fourth memory regions 111, 112, 113 and 114, and the second compressed data DAT_CMP2 is a compression result of compressing the second test area, which includes the fifth to eighth memory regions 115, 116, 117 and 118. If a failure occurs in the first test area, the failure may be detected from the first compressed data DAT_CMP1. If a failure occurs in the second test area, the failure may be detected from the second compressed data DAT_CMP2. In other words, both of the first compressed data DAT_CMP1 and the second compressed data DAT_CMP2 are needed to accurately detect whether the failure occurs in the first test area or in the second test area. Therefore to detect a failure occurring in the memory bank 110, the read operation for the data compression test operation has to be performed twice.

FIG. 2 shows, as an example, a semiconductor memory device performing a data compression test operation without dividing a memory bank 210 into test areas.

Referring to FIG. 2, the semiconductor memory device includes a memory bank 210, a data compressing unit 220, a buffering unit 230, and an output unit 240.

The memory bank 210 stores a test data having a predetermined logic level value during a data compression test operation. The data compressing unit 220 compresses the test data transmitted from first to eighth memory regions 211, 212, 213, 214, 215, 216, 217 and 218 to generate a compressed data DAT_CMP. Herein, the data compressing unit 220 receives the test data from first to eighth memory regions 211, 212, 213, 214, 215, 216, 217 and 218, detects whether the test data have the same logic level value, and outputs the compressed data DAT_CMP. The logic level value of the compressed data DAT_CMP is decided based on the detection result.

Subsequently, the buffering unit 230 buffers the compressed data DAT_CMP and outputs the buffered data as an output signal, and the output unit 240 outputs the output signal of the buffering unit 230 to an output pad DOUT in response to an output control signal CTR_OUT.

As shown in the drawing, the compressed data DAT_CMP is a result of compressing all the regions of the memory bank 210, which are the first to eighth memory regions 211, 212, 213, 214, 215, 216, 217 and 218. Therefore if a failure is detected from the compressed data DAT_CMP, it means that the failure occurred in a test region among the first to eighth memory regions 211, 212, 213, 214, 215, 216, 217 and 218. Therefore, to detect a failure occurring in the memory bank 210, a read operation for the data compression test operation is performed once.

Hereafter, the advantages and disadvantages of each of the example shown in FIG. 1 and the example shown in FIG. 2 are described.

In the example shown in FIG. 1, since the memory bank 110 is divided into two test areas and the data compression test operation is performed on the divided test areas, it is possible to pinpoint which test area a memory region with a failure belongs to among the divided test areas, that is, the first test area (the first to fourth memory regions 111, 112, 113 and 114) and/or the second test area (the fifth to eighth memory regions 115, 116, 117 and 118). On the contrary, since the memory bank 210 is not divided into test areas in the example shown in FIG. 2, it is not possible to pinpoint where a failure occurs among the first to eighth memory regions 211, 212, 213, 214, 215, 216, 217 and 218.

In other words, in the example of FIG. 1, it is possible to detect where the failure occurs between the first test area and/or the second test area, through the data compression test operation, and as a result of the data compression test operation, the first test area, and/or the second test area may be repaired. For example, when a failure occurs in the first to fourth memory regions 111, 112, 113 and 114, the first to fourth memory regions 111, 112, 113 and 114 are repaired. When a failure occurs in the fifth to eighth memory regions 115, 116, 117 and 118, the fifth to eighth memory regions 115, 116, 117 and 118 are repaired. However, in the example of FIG. 2, although a failure occurs in one memory region among the first to eighth memory regions 211, 212, 213, 214, 215, 216, 217 and 218, all the first to eighth memory regions 211, 212, 213, 214, 215, 216, 217 and 218 have to be repaired.

To sum up, whereas the semiconductor memory device shown in the example of FIG. 1 is capable of minimizing the repair range of the memory bank by accurately detecting a test area where a failure occurs, the semiconductor memory device shown in the example of FIG. 2 may repair even a memory bank in which the majority of the memory bank operates properly.

As mentioned before, the semiconductor memory device shown in the example of FIG. 1 performs a read operation for the data compression test operation twice, and the semiconductor memory device shown in the example of FIG. 2 performs a read operation for the data compression test operation once. Herein, the read operation for the data compression test operation corresponds to a test operation time, and the test operation time becomes longer as the number of times that the read operation for the data compression test operation is performed is increased.

In short, while the semiconductor memory device shown in the example of FIG. 2 has the advantage of a short test time for performing the data compression test operation, the semiconductor memory device shown in the example of FIG. 1 takes a relatively long test to perform the data compression test operation.

As described above, repair operation efficiency and test time are in a trade-off relationship with each other. If the repair operation efficiency is increased, the test time becomes longer, and if the test time is short, the repair operation efficiency is decreased.

### SUMMARY

An embodiment of the present invention is directed to a semiconductor memory device that may convert one type of compressed data that are generated during a data compression test into another type.

In accordance with an embodiment of the present invention, a semiconductor memory device may include: a memory bank divided into a plurality of test areas which provide test data for a data compression test operation; a data compressing unit suitable for generating compressed data based on the test data; a data converting unit suitable for converting the compressed data into analog data to generate a final compressed data; and an output unit suitable for outputting the final compressed data during a read operation for the data compression test operation.

The data converting unit may include: a decoder suitable for decoding the compressed data; and a voltage generator suitable for generating the final compressed data having voltage level values respectively corresponding to output signals of the decoder.

The voltage level values corresponding to the output signals of the decoder may be different from each other.

The voltage generator may include: a digital-to-analog converting block suitable for converting the output signals of the decoder into analog signals.

In accordance with another embodiment of the present invention, a semiconductor test system may include: a semiconductor memory device suitable for defining a plurality of test areas in response to compression range information during a data compression test operation, converting compressed data of the plurality of test areas into analog data, and outputting the analog data as a final compressed data; and a test device suitable for detecting a failure from the final compressed data, based on a decision voltage corresponding to the compression range information, and generating a normal/failure detection signal.

The semiconductor memory device may include: a memory bank divided into the plurality of test areas which correspond to the compression range information and provide test data for the data compression test operation; a plurality of data compressing units suitable for generating the compressed data based on the test data, in response to the compression range information; a data converting unit suitable for converting the compressed data into the analog data and generating the final compressed data in response to the compression range information; and an output unit suitable for outputting the final compressed data during a read operation for the data compression test operation.

Among the plurality of data compressing units, the number of enabled data compressing units may be controlled based on the compression range information.

The memory bank may include a plurality of memory regions, and each of the enabled data compressing units may be allocated with a set number of memory regions among the plurality of memory regions based on a data compression rate.

The data converting unit may include: a decoder suitable for decoding the compressed data based on the compression range information; and a voltage generator suitable for generating the final compressed data having voltage level values respectively corresponding to output signals of the decoder.

The voltage generator may include: a digital-to-analog converting block suitable for converting the output signals of the decoder into analog signals.

The test device may include: a result detection unit suitable for setting the decision voltage based on the compression range information, and outputting the final compressed data as the normal/failure detection signal based on the decision voltage.

In accordance with yet another embodiment of the present invention, a method for performing a data compression test operation on a memory bank including a plurality of memory regions may include: grouping the plurality of memory regions into a plurality of test areas based on compression range information; generating compressed data by compressing respective test data of the plurality of test areas; converting the compressed data into analog-type final compressed data; and analyzing a test result by detecting a failure from the final compressed data based on a decision voltage corresponding to the compression range information.

In the grouping of the plurality of memory regions, a different number of memory regions may be grouped into each of the plurality of test areas.

In the grouping of the plurality of memory regions, an extent of deterioration of each of the plurality of memory regions may be reflected.

The converting of the compressed data into the analog-type final compressed data may include: decoding the compressed data; and generating the final compressed data having voltage level values respectively corresponding to output signals of the decoding of the compressed data.

The voltage level values respectively corresponding to the output signals of the decoding of the compressed data may be different from each other.

The analyzing of the test result by detecting the failure from the final compressed data based on the decision voltage corresponding to the compression range information may include: deciding the decision voltage based on the compression range information; and comparing the final compressed data and the decision voltage with each other.

### BRIEF DESCRIPTION OF THE DRAWINGS

FIGS. 1 and 2 are block diagrams illustrating a data compression test operation of a semiconductor memory device according to prior arts.

FIG. 3 is a block diagram illustrating a semiconductor memory device in accordance with an embodiment of the present invention.

FIG. 4 is a block diagram illustrating a data converting unit 330 shown in FIG. 3.

FIG. 5 is a schematic diagram illustrating a voltage generator 420 shown in FIG. 4.

FIG. 6 illustrates a circuit operation of the voltage generator 420 shown in FIGS. 4 and 5.

FIG. 7 is a schematic diagram illustrating an output unit 340 shown in FIG. 3.

FIG. 8 is a block diagram illustrating a semiconductor memory system in accordance with another embodiment of the present invention.

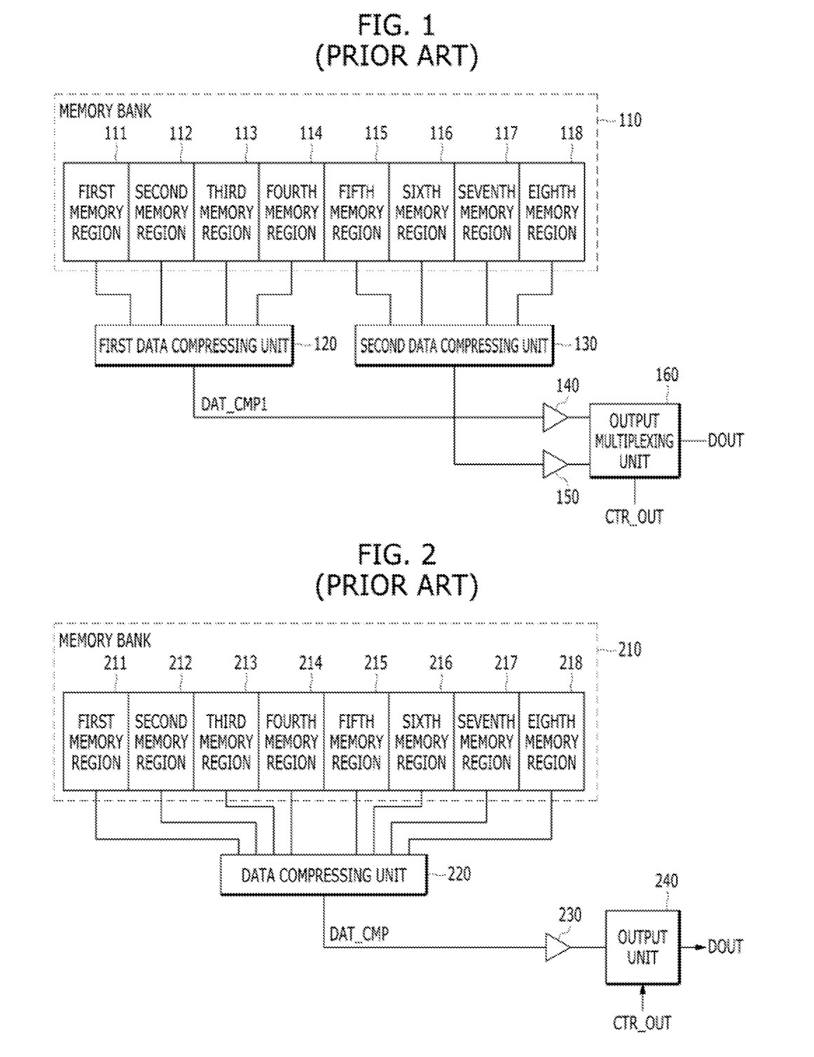

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

When an element is referred to as being connected or coupled to another element, it should be understood that the former can be directly connected or coupled to the latter, or electrically connected or coupled to the latter via an intervening element therebetween. Furthermore, when it is described that one “comprises” (or “includes”) or “has” some elements, it should be understood that it may comprise (or include) only those elements, or it may comprise (or include) or have other elements as well as those elements if there is no specific limitation. The terms of a singular form may include plural forms unless stated otherwise.

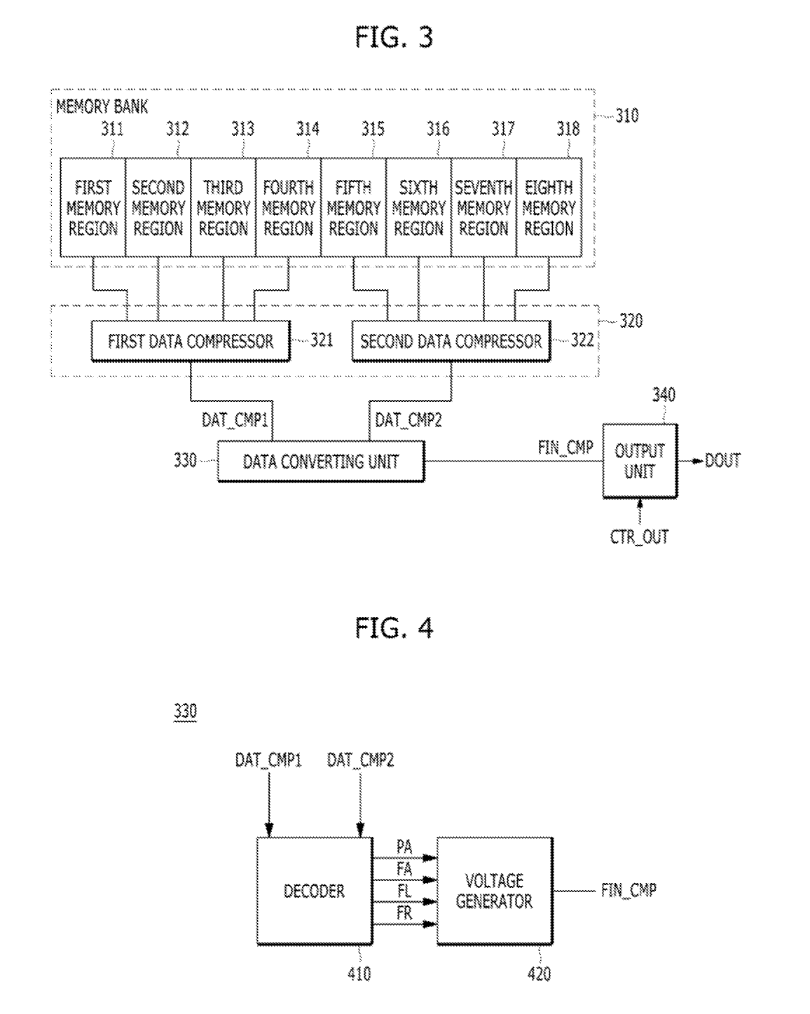

FIG. 3 is a block diagram illustrating a semiconductor memory device in accordance with an embodiment of the present invention. FIG. 3 shows as an example, a semiconductor memory device performing a data compression test operation by dividing a memory bank 310 into two test areas. The semiconductor memory device in accordance with the embodiment of the present invention may perform the data compression test operation by dividing the memory bank 310 into a plurality of test areas, which will be described again later on.

Referring to FIG. 3, the semiconductor memory device includes the memory bank 310, a data compressing unit 320, a data converting unit 330, and an output unit 340.

The memory bank 310 includes a plurality of memory cells for storing data. It is described as an example that the memory bank 310 is divided into 8 memory regions, which are first to eighth memory regions 311, 312, 313, 314, 315, 316, 317 and 318. A test data having a predetermined logic level value is stored in each of the first to eighth memory regions 311, 312, 313, 314, 315, 316, 317 and 318 during the data compression test operation.

The data compressing unit 320 compresses the test data provided by the memory bank 310, and it includes a first data compressor 321 and a second data compressor 322. The first data compressor 321 generates a first compressed data DAT_CMP1 by compressing the test data provided by the first to fourth memory regions 311, 312, 313 and 314, and the second data compressor 322 generates a second compressed data DAT_CMP2 by compressing the test data provided by the fifth to eighth memory regions 315, 316, 317 and 318. Hereafter, the first to fourth memory regions 311, 312, 313 and 314 are referred to as ‘a first test area’, and the fifth to eighth memory regions 315, 316, 317 and 31 are referred to as ‘a second test area’.

The first data compressor 321 detects whether the test data outputted from the first test area have the same logic level value and outputs the detection result as the first compressed data DAT_CMP1, and the second data compressor 322 detects whether the test data outputted from the second test area have the same logic level value and outputs the detection result as the second compressed data DAT_CMP2. The logic level values of the first compressed data DAT_CMP1 and the second compressed data DAT_CMP2 are decided based on the detection results.

Subsequently, the data converting unit 330 converts the first compressed data DAT_CMP1 and the second compressed data DAT_CMP2 into analog data, and outputs the analog data as a final compressed data FIN_CMP. The structure of the data converting unit 330 will be described later with reference to FIG. 4.

Lastly, the output unit 340 outputs the final compressed data FIN_CMP generated in the data converting unit 330 to an output pad DOUT in response to an output control signal CTR_OUT. The output control signal CTR_OUT may be defined as a signal for performing a read operation for a data compression test operation.

The semiconductor memory device in accordance with the embodiment of the present invention may convert compressed data obtained by compressing the data outputted from a plurality of test areas into analog compressed data, and output the analog compressed data.

FIG. 4 is a block diagram illustrating the data converting unit 330 shown in FIG. 3.

Referring to FIGS. 3 and 4, the data converting unit 330 includes a decoder 410 and a voltage generator 420.

The decoder 410 receives and decodes the first compressed data DAT_CMP1 and the second compressed data DAT_CMP2, and outputs the decoded data. For example, the decoder 410 may generate a ‘PA’ output signal, an ‘FA’ output signal, an ‘FL’ output signal and an ‘FR’ output signal based on the logic level values of the first compressed data DAT_CMP1 and the second compressed data DAT_CMP2.

Herein, the ‘PA’ output signal is a signal enabled when the first compressed data DAT_CMP1 and the second compressed data DAT_CMP2 are detected to be normal. The fact that the first compressed data DAT_CMP1 and the second compressed data DAT_CMP2 are detected to be normal signifies that the test data provided by the first to fourth memory regions 311, 312, 313 and 314 are all the same, and the test data provided by the fifth to eighth memory regions 315, 316, 317 and 318 are all the same. In other words, the fact that the first compressed data DAT_CMP1 and the second compressed data DAT_CMP2 are detected to be normal means that no error occurs in the first to fourth memory regions 311, 312, 313 and 314 and the fifth to eighth memory regions 315, 316, 317 and 318.

The ‘FA’ output signal is a signal enabled when the first compressed data DAT_CMP1 and the second compressed data DAT_CMP2 are all detected to be abnormal. The fact that the first compressed data DAT_CMP1 and the second compressed data DAT_CMP2 are all detected to be abnormal signifies that the test data provided by the first to fourth memory regions 311, 312, 313 and 314 are not the same, and the test data provided by the fifth to eighth memory regions 315, 316, 317 and 318 are not the same. In other words, the fact that the first compressed data DAT_CMP1 and the second compressed data DAT_CMP2 are all detected to be abnormal means that an error occurred in the first to fourth memory regions 311, 312, 313 and 314 and in the fifth to eighth memory regions 315, 316, 317 and 318.

The ‘FL’ output signal is a signal enabled when the first compressed data DAT_CMP1 is detected to be abnormal and the second compressed data DAT_CMP2 is detected to be normal. This signifies that a failure has occurred in the first to fourth memory regions 311, 312, 313 and 314, and no failure has occurred in the fifth to eighth memory regions 315, 316, 317 and 318.

Lastly, the ‘FR’ output signal is a signal enabled when the first compressed data DAT_CMP1 is detected to be normal and the second compressed data DAT_CMP2 is detected to be abnormal. This signifies that no failure has occurred in the first to fourth memory regions 311, 312, 313 and 314, and a failure occurred in the fifth to eighth memory regions 315, 316, 317 and 318.

Meanwhile, the voltage generator 420 generates the final compressed data FIN_CMP having logic level values corresponding to the ‘PA’ output signal, the ‘FA’ output signal, the ‘FL’ output signal, and the ‘FR’ output signal, respectively. Herein, the logic level values corresponding to the ‘PA’ output signal, the ‘FA’ output signal, the ‘FL’ output signal, and the ‘FR’ output signal may be set differently from each other. This will be described again later with reference to FIG. 6.

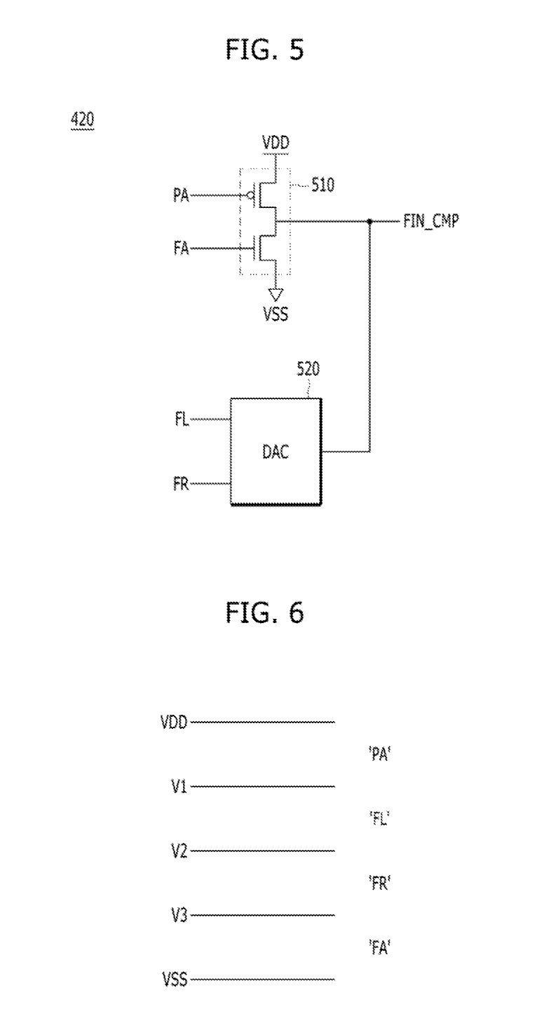

FIG. 5 is a schematic diagram illustrating the voltage generator 420 shown in FIG. 4.

Referring to FIG. 5, the voltage generator 420 includes a driving block 510 and a digital-to-analog converting block (DAC) 520.

The driving block 510 drives the final compressed data FIN_CMP with a power supply voltage VDD or a ground voltage VSS in response to the ‘PA’ output signal and the ‘FA’ output signal. The digital-to-analog converting block 520 generates the final compressed data FIN_CMP having voltage level values corresponding to the ‘FL’ output signal and the ‘FR’ output signal.

FIG. 6 illustrates a circuit operation of the voltage generator 420 shown in FIGS. 4 and 5.

Referring to FIG. 6, as described above, the final compressed data FIN_CMP is analog data. In other words, the final compressed data FIN_CMP has a voltage level value between the power supply voltage VDD and the ground voltage VSS. Responding to the ‘PA’ output signal, the final compressed data FIN_CMP has a voltage level value between the power supply voltage VDD and a first decision voltage V1, and responding to the ‘FL’ output signal, the final compressed data FIN_CMP has a voltage level value between the first decision voltage V1 and a second decision voltage V2. Responding to the ‘FR’ output signal, the final compressed data FIN_CMP has a voltage level value between the second decision voltage V2 and a third decision voltage V3, and responding to the ‘FA’ output signal, the final compressed data FIN_CMP has a voltage level value between the third decision voltage V3 and the ground voltage VSS. A test operation performer may detect the voltage level of the final compressed data FIN_CMP and decide which test area of the memory bank 310 has the failure.

The semiconductor memory device in accordance with the embodiment of the present invention may convert the final compressed data FIN_CMP into analog data and output the analog data, and the test operation performer may detect the voltage level of the final compressed data FIN_CMP and decide whether the memory bank 310 has a failure. In other words, it is possible to accurately detect a failure occurring in a memory bank during a data compression test operation, and this means that the repair operation efficiency may be increased through the data compression test operation.

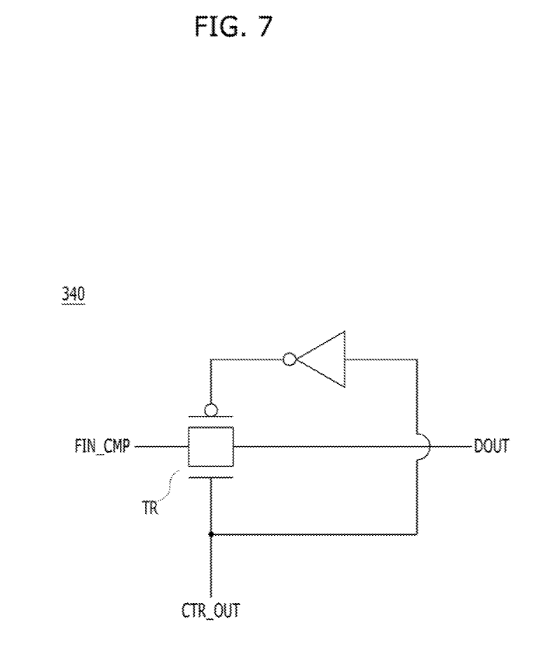

FIG. 7 is a schematic diagram illustrating the output unit 340 shown in FIG. 3.

Referring to FIG. 7, the output unit 340 may output the final compressed data FIN_CMP to the output pad DOUT in response to the output control signal CTR_OUT. The output unit 340 may be formed of a transfer gate TR including a PMOS transistor and an NMOS transistor. Thus, the output unit 340 outputs one data, which is the final compressed data FIN_CMP, to the output pad DOUT in response to the output control signal CTR_OUT.

The semiconductor memory device in accordance with the embodiment of the present invention may output the final compressed data FIN_CMP through a read operation that is performed once for the data compression test operation, thus minimizing the time required for performing the data compression test operation.

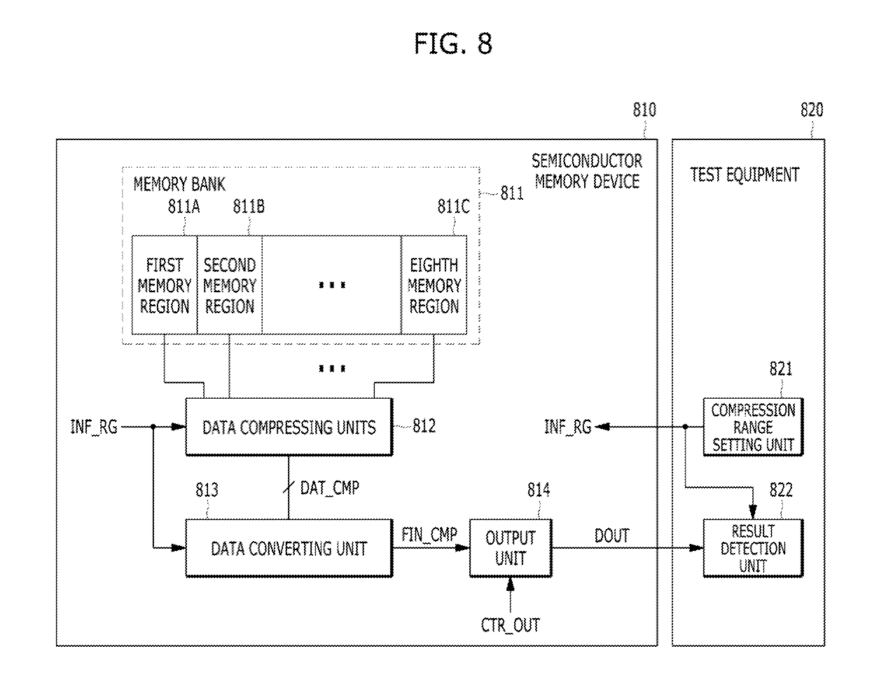

FIG. 8 is a block diagram illustrating a semiconductor memory system in accordance with another embodiment of the present invention.

Referring to FIG. 8, the semiconductor memory system includes a semiconductor memory device 810 and a test device 820.

The semiconductor memory device 810 defines a plurality of test areas in response to compression range information INF_RF, converts compressed data of each test area into analog data, and outputs a final compressed data FIN_CMP. The compression range information INF_RF is information on the test area. The test area may be divided into two test areas as shown in FIG. 3, and of course, it is possible to divide the test area into more than two test areas.

The semiconductor memory device 810 includes a memory bank 811, a plurality of data compressing units 812, a data converting unit 813, and an output unit 814.

The memory bank 811 includes a plurality of memory cells for storing data. It is described as an example that the memory bank 811 is divided into n memory regions, where n is a natural number. In short, the memory bank 811 includes first to n^{th} memory regions 811A, 811B, . . . , 811C. During a data compression test operation, the first to n^{th} memory regions 811A, 811B, . . . , 811C are grouped into test areas, the number of which corresponds to the compression range information INF_RF.

The data compressing units 812 generates a plurality of compressed data DAT_CMP by compressing the test data provided by the memory bank 811. For example, when the memory bank 811 is divided into two test areas as shown in FIG. 3, two data compressing units among the data compressing units 812 are enabled, and the test data of the two test areas are respectively applied to the enabled data compressing units to perform a compression operation. Herein, since the test data of the two test areas are compressed, the number of the compressed data DAT_CMP becomes two. In short, the number of the compressed data DAT_CMP is the same as the number of the test areas.

The data converting unit 813 converts the compressed data DAT_CMP into analog data in response to the compression range information INF_RF. The data converting unit 813 may have the structure shown in FIG. 5. Herein, if the number of test areas is increased, the number of input signals entering the digital-to-analog converting block 520 (DAC, see FIG. 5) is increased.

The output unit 814 outputs a final compressed data FIN_CMP that is generated in the data converting unit 813 to an output pad DOUT in response to an output control signal CTR_OUT. The output unit 814 may have the structure shown in FIG. 7.

The semiconductor memory device 810 in accordance with the embodiment of the present invention may control the number of test areas based on the compression range information INF_RF, and generate final compressed data FIN_CMP corresponding to the test areas.

The test device 820 receives the final compressed data FIN_CMP detects a result based on a decision voltage corresponding to the compression range information INF_RF and generates a normal/failure detection signal PF. The test device 820 includes a compression range setting unit 821 and a result detection unit 822.

The compression range setting unit 821 generates the compression range information INF_RF. The compression range information INF_RF may be set by a test operation performer based on the performances of the test device 820 and the semiconductor memory device 810.

The result detection unit 822 detects the final compressed data FIN_CMP based on the decision voltage corresponding to the compression range information INF_RF through the output pad DOUT of the semiconductor memory device 810. Herein, the number and voltage level of the decision voltage may be set based on the compression range information INF_RF. For example, when there are two test areas in the memory bank 811 and there is the voltage generator 420 of FIG. 5 in the data converting unit 813, the decision voltage may be set to include first to third decision voltages V1, V2 and V3. In short, the result detection unit 822 may compare the final compressed data FIN_CMP with the first to third decision voltages V1, V2 and V3, and accurately detect what memory region a failure occurs in based on the comparison result.

The test device 820 in accordance with the embodiment of the present invention may set the decision voltage based on the compression range information INF_RF and detect the final compressed data FIN_CMP based on the decision voltage. The test operation performer then analyzes the detected normal/failure detection signal PF to decide whether the memory bank 811 of the semiconductor memory device 810 is in a normal condition.

Meanwhile, as described earlier, the number of enabled data compressing units among the data compressing units 812 may be controlled based on the compression range information INF_RF. Herein, the fact that the number of enabled data compressing units is controlled means that the data compression rate may be set during a data compression test operation. It is described as an example that the memory bank includes 12 memory regions, where ‘n’ is 12. When the number of enabled data compressing units changes for the 12 memory regions, a different number of memory regions may be allocated to each of the enabled compressing units. In other words, when the number of enabled data compressing units is 2, six memory regions may be allocated to each of the data compressing units. When the number of enabled data compressing units is 3, four memory regions may be allocated to each of the data compressing units. Herein, the number of allocated memory regions signifies the data compression rate, and controlling the number of memory regions means that the data compression rate is controllable.

Meanwhile, when the number of enabled data compressing units is two, as shown in the above example, the number of memory regions allocated to each of the data compressing units is the same, which is 6 memory regions. In this case, the data compression rate for each data compressing unit is the same. However, the above description that “the data compression rate is controllable” means that the data compression rate of each of the data compressing units may be controlled and set. In short, when it is described as an example that one data compressing unit between the two enabled data compressing units is allocated with 8 memory regions among the 12 memory regions, the other data compressing unit may be allocated with the remaining 4 memory regions. In other words, it is possible to allocate a different number of memory regions to the two data compressing units, and this also means that it is possible to control the two data compressing units to have different data compression rates. In this case, the compression range information INF_RF includes information on the data compression rates of the enabled data compressing units.

The data compression rates of the enabled data compressing units may be set differently for several reasons. Among them is the extent of deterioration of the memory regions in the memory bank 811. In other words, when the memory regions are less deteriorated, more memory regions are allocated to a data compressing unit so that the data compressing unit has a relatively high data compression rate and the data compression test operation is performed. In contrast, when the memory regions are more deteriorated, less memory regions are allocated to a data compressing unit so that the data compressing unit has a relatively low data compression rate and the data compression test operation is performed. In this way, the test time for testing the memory regions with the high data compression rate may be decreased, and the memory regions with the low data compression rate may be tested more thoroughly and exactly to detect a failure occurring therein.

In short, the semiconductor test system in accordance with an embodiment of the present invention may secure optimal test operation conditions during the data compression test operation by controlling the data compression rates of the memory regions based on the extent of deterioration.

According to an embodiment of the present invention, since a semiconductor memory device may generate and output analog-type final compressed data during a data compression test operation, it is possible to accurately detect a failure occurring in a memory bank during the data compression test operation while minimizing the test time required for performing the data compression test operation.

While the present invention has been described with respect to specific embodiments, it will be apparent to those skilled in the art that various changes and modifications may be made without departing from the spirit and scope of the invention as defined in the following claims.

Also, the logic gates and transistors exemplified in the above-described embodiments may be realized in different positions and forms according to the polarity of inputted signals.

What is claimed is:

1. A semiconductor memory device, comprising:
a memory bank divided into a plurality of test areas which provide test data for a data compression test operation;
a data compressing unit suitable for generating compressed data based on the test data;
a data converting unit suitable for converting the compressed data into analog data to generate a final compressed data; and
an output unit suitable for outputting the final compressed data during a read operation for the data compression test operation.

2. The semiconductor memory device of claim 1, wherein the data converting unit includes:
a decoder suitable for decoding the compressed data; and
a voltage generator suitable for generating the final compressed data having voltage level values respectively corresponding to output signals of the decoder.

3. The semiconductor memory device of claim 2, wherein the voltage level values corresponding to the output signals of the decoder are different from each other.

4. The semiconductor memory device of claim 2, wherein the voltage generator includes:
a digital-to-analog converting block suitable for converting the output signals of the decoder into analog signals.

5. A semiconductor test system, comprising:
a semiconductor memory device suitable for defining a plurality of test areas in response to compression range information during a data compression test operation, converting compressed data of the plurality of test areas into analog data, and outputting the analog data as a final compressed data; and
a test device suitable for detecting a failure from the final compressed data, based on a decision voltage corresponding to the compression range information, and generating a normal/failure detection signal.

6. The semiconductor test system of claim 5, wherein the semiconductor memory device includes:
a memory bank divided into the plurality of test areas which correspond to the compression range information and provide test data for the data compression test operation;
a plurality of data compressing units suitable for generating the compressed data based on the test data, in response to the compression range information;
a data converting unit suitable for converting the compressed data into the analog data and generating the final compressed data in response to the compression range information; and
an output unit suitable for outputting the final compressed data during a read operation for the data compression test operation.

7. The semiconductor test system of claim 6, wherein, among the plurality of data compressing units, the number of enabled data compressing units is controlled based on the compression range information.

8. The semiconductor test system of claim 7, wherein the memory bank includes a plurality of memory regions, and
each of the enabled data compressing units is allocated with a set number of memory regions among the plurality of memory regions based on a data compression rate.

9. The semiconductor test system of claim 6, wherein the data converting unit includes:
a decoder suitable for decoding the compressed data based on the compression range information; and
a voltage generator suitable for generating the final compressed data having voltage level values respectively corresponding to output signals of the decoder.

10. The semiconductor test system of claim 9, wherein the voltage generator includes:
a digital-to-analog converting block suitable for converting the output signals of the decoder into analog signals.

11. The semiconductor test system of claim 5, wherein the test device includes:
a result detection unit suitable for setting the decision voltage based on the compression range information, and outputting the final compressed data as the normal/failure detection signal based on the decision voltage.

12. A method for performing a data compression test operation on a memory bank including a plurality of memory regions, comprising:
grouping the plurality of memory regions into a plurality of test areas based on compression range information;
generating compressed data by compressing respective test data of the plurality of test areas;
converting the compressed data into analog-type final compressed data; and
analyzing a test result by detecting a failure from the final compressed data based on a decision voltage corresponding to the compression range information.

13. The method of claim 12, wherein in the grouping of the plurality of memory regions,
a different number of memory regions are grouped into each of the plurality of test areas.

14. The method of claim 12, wherein in the grouping of the plurality of memory regions,
an extent of deterioration of each of the plurality of memory regions is reflected.

15. The method of claim 12, wherein the converting of the compressed data into the analog-type final compressed data includes:
decoding the compressed data; and
generating the final compressed data having voltage level values respectively corresponding to output signals of the decoding of the compressed data.

16. The method of claim 15, wherein the voltage level values respectively corresponding to the output signals of the decoding of the compressed data are different from each other.

17. The method of claim 12, wherein the analyzing of the test result by detecting the failure from the final compressed data based on the decision voltage corresponding to the compression range information includes:
deciding the decision voltage based on the compression range information; and
comparing the final compressed data and the decision voltage with each other.
